(19) United States
(12) Patent Application Publication
(10) Pub. No.: US 2023/0292468 A1
(43) Pub. Date: Sep. 14, 2023

(54) RADIATION SHEET, HEAT DISSIPATION PLATE, HEAT DISSIPATION DEVICE AND CURABLE PASTE

(71) Applicant: TOKYO OHKA KOGYO CO., LTD., Kawasaki-shi (JP)

(72) Inventors: Isao HIRANO, Kawasaki-shi (JP); Yasushi FUJII, Kawasaki-shi (JP)

(21) Appl. No.: 18/179,942

(22) Filed: Mar. 7, 2023

(30) Foreign Application Priority Data
Mar. 9, 2022 (JP) 2022-036550
Feb. 1, 2023 (JP) 2023-014243

(51) Int. Cl. H05K 7/20

(52) U.S. Cl. CPC H05K 7/2039

(57) ABSTRACT

To provide a radiation sheet that exhibits favorable heat dissipating performance, a heat dissipation plate including the radiation sheet, a heat dissipation device provided with the heat dissipation plate, and a curable paste capable of being suitably used for forming the above-mentioned radiation sheet. A sheet including a cured material of a curable paste that contains a polymerizable monomer (A) having only an ethylenic unsaturated double bond-containing group as a polymerizable group, a radical polymerization initiator (B) and a layered silicate (C) is used as a radiation sheet.

### BACKGROUND OF THE INVENTION

### Field of the Invention

The present invention relates to a radiation sheet capable of absorbing and dissipating heat, a heat dissipation device that absorbs and dissipates heat generated by a heating element such as an electronic part, and a heat dissipation plate.

### Related Art

Conventional heat dissipation devices include, for example, a fin-type heat sink. The heat sink is mounted on an outer surface of a heating element such as an electronic part. Heat of the heating element transferred to the heat sink is dissipated to the atmosphere from fins, or dissipated to the atmosphere by forcibly generating convection in air between fins using a blower (for example, see Patent Document 1).

Patent Document 1: Japanese Unexamined Patent Application, Publication No. 2020-155521

### SUMMARY OF THE INVENTION

The conventional heat dissipation device dissipates heat by making use of heat conduction. Accordingly, it is necessary to provide a part having a low temperature such as a heat sink. In this case, there is a concern that the device becomes large-sized. On the other hand, in the case where the heat dissipation is performed by making use of radiation, heat can be dissipated without using a fin-type heat sink or a blower. Accordingly, it is expected that efficient heat dissipation can be achieved while realizing the downsizing of a heat dissipation device or equipment provided with a heat dissipation device.

The present invention has been made in view of the above-mentioned problems, and it is an object of the present invention to provide a radiation sheet that exhibits a favorable heat dissipating performance, a heat dissipation plate formed of the radiation sheet, a heat dissipation device provided with the heat dissipation plate, and a curable paste capable of being suitably used for forming the above-mentioned radiation sheet.

Inventors of the present invention have found that the above-mentioned problems can be solved by using, as a radiation sheet, a sheet including a cured material of a curable paste that contains a polymerizable monomer (A) having only an ethylenic unsaturated double bond-containing group as a polymerizable group, a radical polymerization initiator (B) and a layered silicate (C), leading to the completion of the present invention. More specifically, the present invention provides the following.

According to a first aspect of the present invention, there is provided a radiation sheet including:
a cured material of a curable paste that contains a polymerizable monomer (A),
a radical polymerization initiator (B) and
a layered silicate (C),
the polymerizable monomer (A) having only an ethylenic unsaturated double bond-containing group as a polymerizable group.

According to a second aspect of the present invention, there is provided a heat dissipation plate including the radiation sheet according to the first aspect, wherein the heat dissipation plate has a heat absorbing surface that is formed on one surface of the heat dissipation plate and absorbs heat dissipated from a heat generation source, and a heat dissipating surface that is formed on the other surface of the heat dissipation plate and dissipates at least a part of the heat that is absorbed from the heat absorbing surface.

According to a third aspect of the present invention, there is provided a heat dissipation device that includes the heat dissipation plate according to the second aspect.

According to a fourth aspect of the present invention, there is provided a curable paste that is used for forming the radiation sheet according to the first aspect, wherein

the curable paste including a polymerizable monomer (A), a radical polymerization initiator (B) and a layered silicate (C),

the polymerizable monomer (A) having only an ethylenic unsaturated double bond-containing group as a polymerizable group.

According to the present invention, it is possible to provide a radiation sheet that exhibits a favorable heat dissipating performance, a heat dissipation plate formed of the radiation sheet, a heat dissipation device provided with the heat dissipation plate, and a curable paste capable of being suitably used for forming the above-mentioned radiation sheet.

### BRIEF DESCRIPTION OF THE DRAWINGS

FIG. 1 is a cross-sectional view of an electronic equipment to which a heat dissipation device according to a first embodiment of the present invention is applied.

### DETAILED DESCRIPTION OF THE INVENTION

### Radiation Sheet

The radiation sheet is formed of a cured material made of a curable paste that contains a polymerizable monomer (A), a radical polymerization initiator (B) and a layered silicate (C). The polymerizable monomer (A) includes only an ethylenic unsaturated double bond-containing group as the polymerizable group. The above-mentioned radiation sheet exhibits a favorable heat dissipating performance although the radiation sheet is thin and light-weight.

### Curable Paste

As described above, the curable paste contains a polymerizable monomer (A), a radical polymerization initiator (B) and a layered silicate (C). Hereinafter, indispensable or arbitrary components that the curable paste can contain are described.

### Polymerizable Monomer (A)

The polymerizable monomer (A) is a compound that is cured by an action of the radical polymerization initiator (B). The polymerizable monomer (A) is a compound that includes a group that only contains an ethylenic unsaturated double bond as a polymerizable group.

As the polymerizable monomer (A), it is preferable to use a compound that includes one or more (meth) acryloyl group such as a (meth) acrylate compound or a (meth) acrylamide compound, and it is more preferable to use a (meth) acrylate compound that includes one or more (meth) acryloyl group. The polymerizable monomer (A) may be a monofunctional polymerizable monomer that includes one ethylenic unsaturated double bond-containing group or a polyfunctional polymerizable monomer that includes two or more ethylenic unsaturated double bond-containing groups. A monofunctional polymerizable monomer and a polyfunctional compound monomer may be used in combination. From the viewpoint of strength and polymerization reactivity, it is desirable to have the polymerizable monomer (A) include a polyfunctional polymerizable monomer.

Examples of monofunctional polymerizable monomers include, (meth)acrylamide, methylol(meth)acrylamide, methoxymethyl (meth) acrylamide, ethoxymethyl(meth)acrylamide, propoxymethyl(meth)acrylamide, butoxymethoxymethyl(meth)acrylamide, N-methylol(meth)acrylamide, N-hydroxymethyl(meth)acrylamide, (meth)acrylic acid, fumaric acid, maleic acid, maleic acid anhydride, itaconic acid, itaconic acid anhydride, citraconic acid, citraconic acid anhydride, crotonic acid, 2-acrylamide -2-metyhpropanesulfonic acid, tert-butylacrylamide sulfonic acid, methyl(meth) acrylate, ethyl(meth) acrylate, butyl(meth) acrylate, 2-ethylhexyl(meth)acrylate, cyclohexyl(meth)acrylate, 2-hydroxyethyl(meth)acrylate, 2-hydroxypropyl(meth)acrylate, 2-hydroxy butyl(meth)acrylate, 2-phenoxy-2-hydroxypropyl(meth)acrylate, 2-(meth)acryloyloxy-2-hydroxypropyl phthalate, glycerin mono(meth)acrylate, tetrahydrofurfuryl(meth)acrylate, dimethylamino(meth)acrylate, glycidyl(meth)acrylate, 2,2,2-trifluoroethyl(meth)acrylate, 2,2,3,3-tetrafluoro propyl(meth)acrylate, half (meth)acrylate of phthalic acid derivative, or the like. These monofunctional polymerizable monomers can be used singly or in a combination of two or more types of monofunctional polymerizable monomers.

Examples of polyfunctional polymerization monomers include ethylene glycol di(meth)acrylate, diethylene glycol di(meth)acrylate, tetraethylene glycol di(meth)acrylate, polyethylene glycol di(meth)acrylate, propyleneglycol di(meth)acrylate, poly propyleneglycol di(meth)acrylate, butylene glycol di(meth)acrylate, neopentyl glycol di(meth)acrylate, 1,6-hexane glycol di(meth)acrylate, 1,7-heptane diol di(meth)acrylate, 1,8-octanediol di(meth)acrylate, 1,9-nonanediol di(meth)acrylate, dimethylol tricyclodecane di(meth)acrylate, trimethylolpropane tori(meth)acrylate, glycerin di(meth)acrylate, pentaerythritol di(meth)acrylate, pentaerythritol tori(meth)acrylate, pentaerythritol tetra(meth)acrylate, dipentaerythritol penta(meth)acrylate, dipentaerythritol hexa(meth)acrylate, 2,2-bis(4-(meth)acryloxy diethoxyphenyl)propane, 2,2-bis(4-(meth)acryloxy polyethoxy phenyl) propane, 2-hydroxy-3-(meth)acryloyloxypropyl(meth)acrylate, ethylene glycol diglycidyl ether di(meta)acrylate, diethylene glycol diglycidyl ether di(meth)acrylate, phthalic acid diglycidyl ester di(meth)acrylate, glycerol triacrylate, glycerin poly glycidyl ether poly(meth)acrylate, urethane(meth)acrylate (that is, tolylene diisocyanate), a reactant of trimethyl hexamethylene di-isocyanate, hexamethylene di-isocyanate, and 2-hydroxyethyl(meth)acrylate, multifunctional compounds, such as a condensation product of methylenebis(meth)acrylamide,(meth)acrylamide methylene ether, of polyhydric alcohol and N-methylol(meth)acrylamide, triacrylformal and the like. These polyfunctional compounds can be used singly or in a combination of two or more polyfunctional polymerizable monomers.

In the above-mentioned polyfunctional polymerization monomers, it is preferable to use ethylene glycol di(meth)acrylate, diethylene glycol di(meth)acrylate, tetraethylene glycol di(meth)acrylate, poly ethylene glycol di(meth)acrylate, propyleneglycol di(meth)acrylate, poly propyleneglycol di(meth)acrylate, butylene glycol di(meth)acrylate, neopentyl glycol di(meth)acrylate, 1,6-hexane glycol di(meth)acrylate, 1,7-heptane diol di(meth)acrylate, 1,8-octanediol di(meth)acrylate, di(meth)acrylate of glycols, such as 1,9-nonanediol di(meth)acrylate and dimethylol tricyclodecane di(meth)acrylate.

From the viewpoint of the strength, flexibility and the like of a cured material, as a polymerization monomer (A), it is preferable to use di(meth)acrylate of glycols, polyfunctional urethane(meth)acrylate, and(meth)acryloyl group-containing resin, and it is more preferable to use di(meth)acrylate of glycols, and polyfunctional urethane(meth)acrylate.

Specific examples of a suitable polyfunctional urethane(meth)acrylate include each product of Blemmer DA series (manufactured by NOF CORPORATION), each product of Blemmer DP series (manufactured by NOF CORPORATION), each product of NK OLIGO U series (manufactured by SHIN-NAKAMURA CHEMICAL CO, LTD.), each product of NK OLIGO UA series (manufactured by SHIN-NAKAMURA CHEMICAL CO, LTD.), ARONIX M-1100 (manufactured by Toagosei Chemical Industry Co., Ltd.), ARONIX M-1200 (manufactured by Toagosei Chemical Industry Co., Ltd.), each product of KAYARAD UF series (manufactured by Nippon Kayaku Co., Ltd.), each product of KAYARAD UXF series (manufactured by Nippon Kayaku Co., Ltd.), each product of Beamset 500 series (manufactured by ARAKAWA CHEMICAL INDUSTRIES, LTD.), each product of SHIKOH series (manufactured by Mitsubishi Chemical Corporation), each product of EBECRYL series (manufactured by DAICEL-ALLNEX LTD.), each product of Art Resin series (manufactured by Negami Chemical Industrial Co., Ltd.), each product of NISSO PB/TE series (manufactured by Nippon Soda Co., Ltd.), or the like.

A (meth)acryloyl group-containing resin is a (meth)acryloyl group-containing silicone resin which has a unit derived from a silane compound having a (meth)acryloyl group such as 3-(meth)acryloyloxypropyl trimethoxysilane. The resin obtained by a reaction of (meth)acrylic resin having a carboxy group and a (meth)acrylic acid derivative having epoxy group such as glycidyl(meth)acrylate, or a resin obtained by reaction of(meth)acrylic resin having an epoxy group and a (meth)acrylic acid can also be used as a (meth)acryloyl group-containing resin.

The polymerizable monomer (A) is used such that a ratio of a mass of the layered silicate (C) with respect to a mass of radiation sheet made of a cured material is preferably 20% by mass or more and 80 by mass or less, and more preferably 25% by mass or more and 60% by mass or less. A use amount of the polymerizable monomer (A) in the curable paste is preferably 20% by mass or more and 80% by mass or less, and more preferably 40% by mass or more and 75% by mass or less with respect to a sum of the mass of polymerizable monomer (A) and the mass of the layered silicate (C).

### Radical Polymerization Initiator (B)

The curable paste contains a radical polymerization initiator (B) as a component that cures the curable paste by polymerizing the polymerizable monomer (A). The radical polymerization initiator (B) is not particularly limited, and a conventionally known photopolymerization initiator, a conventionally known thermal polymerization initiator and the like can be used.

Specific examples of a photopolymerization initiator include 1-hydroxy cyclohexyl phenyl ketone, 2-hydroxy-2-methyl-1-phenylpropane-1-one, 1-(4-(2-hydroxy ethoxy)phenyl) -2-hydroxy-2-methyl-1-propane-1-one, 1-(4-isopropylpheny1)-2-hydroxy-2-methylpropane-1-one, 1-(4-dodecylphenyl)-2-hydroxy -2-methylpropane-1-one, 2,2-dimethoxy-1,2-diphenylethane-1-one, bis(4-dimethylaminophenyl)ketone, 2-methyl-1-(4-(methylthio)phenyl)-2-morpholinopropane-1-one, 2-benzyl-2-dimethylamino-1-(4-morpholinopheny)-butane-1-one, 1,2-octanedione, 1-(4-(phenylthio)phenyl)-2-(O -benzoyloxime)(Irgacure OXE01), ethanone-1-(9-ethyl-6-(2methylbenzoyl)-9H-carbazol-3-yl)-1-(O-acetyloxime) (Irgacure OXE02), 2,4,6-trimethyl benzoyldiphenyl phosphine oxide(Omnirad TPO H), bis(2,4,6-trimethyl benzoyl)phenylphosphine oxide(Omnirad 819), 4-benzoyl-4′-methyldimethylsulfide, a 4-dimethylaminobenzoic acid, 4-dimethylaminobenzoic acid methyl, 4-dimethylaminobenzoic acid ethyl, 4-dimethylaminobenzoic acid butyl, a 4-dimethylamino-2-ethylhexyl benzoic acid, a 4-dimethylamino-2-isoamyl benzoic acid, benzyl-β-methoxy ethyl acetal, benzyl dimethyl ketal, 1-phenyl-1,2-propanedione-2-(O-ethoxycarbonyl) oxime, methyl O-benzoylbenzoate, 2,4-diethylthio xanthone, 2-chlorothioxanthone, 2,4-dimethylthioxantone, l-chloro-4-propoxythioxanthone, thioxanthene, 2-chlcrothioxanthene, 2,4-diethylthioxanthene, 2-methyltihoxanthene, 2-isopropylthioxanthene, 2-ethylanthraquinone, octamethylanthraquinone, 1,2-benzanthraquinone, 2,3-diphenylanthraquinone, azobisisobutyronitrile, benzoyl peroxide, cumene hydroperoxide, 2-mercaptobenzimidazole, 2-mercaptobenzooxazol, 2-mercaptobenzothiazole, 2-(O -chlorophenyl)-4,5-di(m-methoxyphenyl)-imidazolyl dimer, benzophenone, 2-chlorobenzophenone, p,p′-bisdimethyl aminobenzophenone, 4,4′-bis diethylamino benzophenone, 4,4′-dichloro benzophenone, 3,3-dimethyl-4-methoxybenzophenone, benzyl, benzoin, benzoin methyl ether, benzoin ethyl ether, benzoin iso-propyl ether, benzoin-n-butyl ether, benzoin isobutyl ether, benzoin butyl ether, acetophenone, 2,2-diethoxy acetophenone, p-dimethylacetophenone, p-dimethylamino propiophenone, dichloroacetophenone, trichloroacetophenone, p-tert-butyl acetophenone, p-dimethylamino acetophenone, p-tert -butyl trichloro acetophenone, p-tert-butyl dichloroacetophenone, α,α-dichloro-4-phenoxyacetophenone, thioxanthone, 2-methyl thioxanthone, 2-isopropyl thioxanthone, dibenzosuberone, pentyl-4-dimethylamino benzoate, 9-phenylacridine, 1,7-bis-(9-acridinyl)heptane, 1,5-bis-(9-acridinyl)pentane, 1,3-bis-(9-acridinyl)propane, p-methoxy triazine, 2,4,6-tris (trichloromethyl)-s-triazine, 2-methyl -4,6-bis(trichloromethyl)-s-triazine, 2-[2-(5-methylfuran-2-yl)ethenyl]-4,6-bis(trichloromethyl)-s-triazine, 2-[2-(furan -2-yl)ethenyl]-4,6-bis(trichloromethyl)-s-triazine, 2-[2-(4-diethylamino-2-methylphenyl)ethenyl]-4,6-bis(trichloromethyl) -s-triazine, 2-[2-(3,4-dimethoxy phenyl)ethenyl]-4,6-bis(trichloromethyl)-s-triazine, 2-(4-methoxyphenyl)-4,6-bis(trichloromethyl)-s-triazine, 2-(4-ethoxy styryl)-4,6-bis(trichloromethyl)-s-triazine, 2-(4-n-butoxy phenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl -6-(3-bromo-4-methoxy)styryl phenyl-s-triazine, 2,4-bis -trichloromethyl-6-(2-bromo-4-methoxy)styryl phenyl-s-triazine, and the like. These photo polymerization initiators can be used singly or in a combination of two or more types of photo polymerization initiators.

As the thermal polymerization initiator, it is possible to use organic peroxide or an azo compound. Specific examples of an organic peroxide includes ketone peroxide such as methyl-ethyl-ketone peroxide and cyclohexanone peroxide; peroxy ketal such as 2,2-bis(tert-butylperoxy)butane and 1,1-bis(tert -butylperoxy)cyclohexane; hydroperoxide such as tert-butyl hydroperoxide and cumene hydroperoxide; dialkyl peroxide such as di-tert-butyl peroxide(perbutyl (registered trademark) D (manufactured by NOF CORPORATION) and di-tert-hexyl peroxide(perhexyl (registered trademark) D (manufactured by NOF CORPORATION); diacyl peroxide such as isobutyryl peroxide, lauroyl peroxide, and benzoyl peroxide; peroxy dicarbonate such as diisopropyl peroxy dicarbonate; peroxy ester such as tert-butylperoxy isobutyrate and 2,5-dimethyl-2,5-di(benzoylperoxy) hexane, and the like. Specific examples of an azo compound include 1,1′-azobis(cyclohexane-1-carbonitrile), 2,2′-azobisisobutyronitrile, 2,2′-azobis(2,4-dimethyl-4-methoxy valeronitrile), 2,2′-azobis(2-methylpropionamidin) dihydrochloride, 2,2′-azobis[2-methyl-N -(2-propenyl)propionamidin]dihydrochloride, 2,2′-azobis (2-methylpropionamide), 2,2′-azobis[2-methyl-N-(2-hydroxyethyl)propionamide], 2,2′-azobis(2-methylpropane), 2,2′-azobis(2,4,4-trimethyl pentane), dimethyl 2,2′-azobis(2-methyl propionate), and the like. These thermal polymerization initiators can be used singly or in a combination of two or more types of thermal polymerization initiators.

The content of the radical polymerization initiator (B) in the curable paste is not particularly limited provided that the curable paste is favorably cured by heating and/or light exposure. In the case of the curable paste not containing a dispersion medium, the content of the radical polymerization initiator (B) is preferably 0.1% by mass or more and 20% by mass or less, more preferably 0.5% by mass or more and 15% by mass or less, and even more preferably 1% by mass or more and 10% by mass or less with respect to the mass of the curable paste. In the case of the curable paste containing a dispersion medium described later, the content of the radical polymerization initiator (B) is preferably 0.1% by mass or more and 20% by mass or less, more preferably 0.5% by mass or more and 15% by mass or less, and even more preferably 1% by mass or more and 10% by mass or less with respect to the mass obtained by subtracting the mass of the dispersion medium from the mass of the curable paste.

### Layered Silicate (C)

The layered silicate (C) is a component that imparts a heat dissipating property generated by radiation to the cured material by using the layered silicate (C) in combination with the above-mentioned polymerizable monomer (A).

The layered silicate (C) is not particularly limited provided that desired advantageous effects are not impaired. The layered silicate (C) can be suitably selected from known layered silicates. As the layered silicate, for example, isinglass (mica), smectite, talc, kaolin, pyrophyllite, sericite, and the like can be used. Kaolin can be easily commercially available, can be uniformly and easily dispersed in the cured material, and can easily form the cured material having excellent heat dissipating properties. Accordingly, the layered silicate (C) preferably contains kaolin, and more preferably contains only kaolin.

A particle size of the layered silicate (C) is not particularly limited. From the viewpoint of facilitating the uniform dispersion of the layered silicate (C) in the cured material made of the above-mentioned curable paste and the formation of the cured material having favorable heat dissipating property, the particle size of the layered silicate (C) is preferably 0.1 μm to 40 μm. The particle size of the layered silicate (C) can be measured as a volume average particle size using a laser diffraction particle size distribution analyzer.

In the curable paste, the layered silicate (C) is used such that a ratio of the mass of the layered silicate (C) with respect to the mass of the radiation sheet is preferably 20% by mass or more and 80% by mass or less, and is more preferably 25% by mass or more and 60% by mass or less. A use amount of the layered silicate (C) in the curable paste is preferably 20% by mass or more and 80% by mass or less, and more preferably 25% by mass or more and 60% by mass or less with respect to the sum of the mass of the polymerizable monomer (A) and the mass of the layered silicate (C).

### Other Components

The curable paste may contain a dispersion medium for the purpose of preparing a coating property of the paste. The dispersion medium may be water, an organic solvent or an aqueous solution of an organic solvent. In manufacturing the radiation sheet using the curable paste, it is necessary to remove the dispersion medium by drying. Due to reasons including such a reason, the curable paste preferably does not contain a dispersion medium.

Further, the curable paste may contain various types of additives provided that desired purposes are not impaired. Additives may include a dispersing agent, an oxidation preventing agent, a deflocculating agent, a defoaming agent, a viscosity adjusting agent, a pigment, a dye and the like.

### Method for Manufacturing Radiation Sheet

A film is formed using the curable paste described above. Then, depending on the type of the radical polymerization initiator (B), the radiation sheet that is formed of the cured material produced from the curable paste can be manufactured by applying light exposure to and/or heating the composition formed as a film.

First, a coating film is formed by applying the curable paste onto a substrate or a support film such as a PET film by coating. In the case where the coating film contains a dispersion medium, when necessary, at least a portion of the dispersion medium may be removed from the coating film.

A method for applying the curable paste by coating is not particularly limited. For example, a contact transfer type coater such as a roll coater, a reverse coater, a bar coater or a slit coater, or a non-contact type coater such as a spinner (a rotary coater) or a curtain flow coater can be used. Further, as the method for forming the coating film, it is also possible to apply a printing method such as a screen-printing method or an inkjet printing method.

The film thickness of the coating film formed as described above is not particularly limited. From the viewpoint of radiation performance of the radiation sheet, the film thickness of the coating film is suitably adjusted such that the radiation sheet having the film thickness of preferably 400 μm or more and 2500 μm or less, and more preferably 400 μm or more and 2000 μm or less is formed.

By applying light exposure to and/or heating the coating film after the coating film is formed by the above-mentioned method, it is possible to obtain the radiation sheet.

The condition for applying light exposure to the coating film is not particularly limited provided that the curing progresses favorably. The light exposure is performed by an irradiating active energy beam such as an X ray, a gamma beam, an ultraviolet beam, a visible beam or an excimer laser beam, for example. The dose of energy to be irradiated is not particularly limited. However, for example, the dose of energy to be irradiated may be 30 mJ/cm² or more and 5000 mJ/cm² or less. The light exposure may be applied to only one surface of the coating film, or may be applied to both surfaces of the coating film. The condition for heating the coating film is not particularly limited provided that the curing favorably progresses. The curing is, for example, performed at a temperature of 90° C. or higher and 180° C. or lower for 1 minute or longer and 30 minutes or shorter.

### Heat Dissipation Device, Heat Dissipation Plate

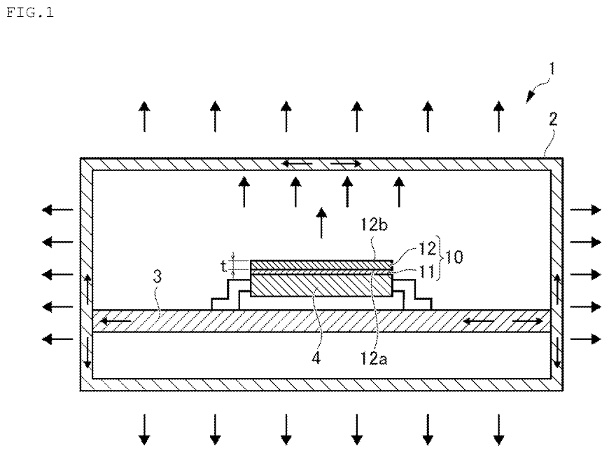

FIG. 1 illustrates the first embodiment of the present invention. FIG. 1 is a cross-sectional view of the electronic equipment to which the heat dissipation device is applied.

The heat dissipation device 10 according to the present embodiment is, as illustrated in FIG. 1, applicable to the electronic equipment 1.

The electronic 1 includes: a housing 2; a substrate 3 that is mounted in the housing 2; an electronic component 4 that is mounted on the 3 as a heat generation source; the heat dissipation device 10 according to the present invention that is mounted on the electronic component 4.

The electronic component 4 is, for example, a component that emits heat during its operation such as a central processing unit (CPU) or the like.

The heat dissipation device includes a heat dissipation plate 12 provided for dissipating heat that the electronic component 4 generates by thermal radiation. Typically, the heat dissipation device 10 includes, together with the heat dissipation plate 12, a thermally conductive material 11 that transfers heat emitted from the electronic component 4 to the heat dissipation plate 12.

As the thermally conductive material 11 is, for example, a sheet-shaped member made of a resin to which a filler such as alumina, silicon nitride or aluminum nitride is added, a metal substrate made of alumina, silicon nitride or aluminum nitride, thermally conductive grease and the like are exemplified. However, the thermally conductive material 11 is not limited to these materials. As the thermally conductive material 11, the material that is laminated to an outer surface of the electronic component 4 is exemplified. However, the thermally conductive material 11 is not limited to such a material. With respect to the configuration of the thermally conductive material 11, any configuration may be adopted provided that heat emitted from the electronic component 4 is transferred over the entire surface of the heat dissipation plate 12. Particularly, in the case where a side of the heat dissipation plate 12 having a heat absorbing surface 12a is formed in a flat plate shape, the thermally conductive material 11 may preferably have the configuration that can transfer heat emitted from the electronic component 4 to the heat dissipation plate 12 irrelevant to an outer surface shape of the electronic component . For example, the thermally conductive material 11 in a grease form or a paste form, and the thermally conductive material 11 in a gel form are preferably used. More specifically, for example, in the case where the electronic component 4 is a CPU, the above-mentioned curable paste may be directly applied, by coating, to a metal-made heat spreader integrated with the CPU, and the heat dissipation plate 12 may be formed on the metal heat spreader. As described later, the heat dissipation plate 12 is formed of the radiation sheet described above. In the case where the above-mentioned curable paste cannot be directly applied to the metal-made heat spreader by coating, a member made of the thermally conductive material 11 is mounted on both ends of the metal-made heat spreader, and the heat dissipation plate 12 formed of the above-mentioned radiation sheet is mounted on the members such that the heat dissipation plate 12 is brought into contact with the thermally conductive material 11. In the case where the electronic component 4 is a chip that does not include a metal-made heat spreader, a metal-made heat spreader may be mounted on the chip and, thereafter, the above-mentioned curable paste is directly applied to the metal-made heat spreader by coating, and the heat dissipation plate 12 may be formed on the metal heat spreader. With respect to the electronic component 4 being a chip that does not include the metal-made heat spreader, in the case where the above-mentioned curable paste cannot be directly applied to the metal-made spreader by coating at the time of forming the heat dissipation plate 12 after mounting the metal-made heat spreader to the chip, a member made of the thermally conductive material 11 is mounted on both ends of the metal-made heat spreader, and the heat dissipation plate 12 formed of the above-mentioned radiation sheet is mounted on the member such that the heat dissipation plate 12 is brought into contact with the thermally conductive material 11.

The heat dissipation plate 12 is formed of the above-mentioned radiation sheet. The heat dissipation plate 12 has: the heat absorbing surface 12a that is formed on one surface of the heat dissipation plate 12, and absorbs heat emitted from the electronic component 4; and a heat dissipating surface 12b that is formed on the other surface of the heat dissipation plate 12 and dissipates at least a portion of heat absorbed from the heat absorbing surface 12a as electromagnetic waves.

The heat absorbing surface 12a of the heat dissipation plate 12 is brought into contact with the thermally conductive material 11. The heat absorbing surface 12a is preferably brought into contact with the thermally conductive material 11 over its entire surface. The heat dissipating surface 12b of the heat dissipation plate 12 faces an inner surface of the housing 2 with a gap formed between the heat dissipating surface 12b and the inner surface of the housing 2.

In the electronic 1 having the above-mentioned configuration, a portion of heat emitted from the electronic component 4 is transferred to the housing 2 through the substrate 3 due to thermal conduction. A remaining heat that is emitted from the electronic component 4 is transferred to the housing 2 through the heat dissipation device 10 by thermal radiation and convection. Heat transferred to the housing 2 is dissipated to air outside the housing 2.

Further, heat transferred to the heat dissipation device 10 from the electronic component 4 is absorbed into the heat dissipation plate 12 from the entire surface of the heat absorbing surface 12a. Further, at least a portion of heat that the heat dissipation plate 12 absorbs is dissipated from the entire surface of the heat dissipating surface 12b as electromagnetic waves by thermal radiation, and is transferred to the inner surface of the housing 2.

In the above-mentioned embodiment, the description is made with respect to the heat dissipation device 10 that includes the thermally conductive material 11 and the heat dissipation plate 12. However, the heat dissipation device may be a device that includes a member different from the thermally conductive material 11 provided that the device includes the heat dissipation plate 12 according to the present invention.

Further, in the above-mentioned embodiment, the description has been made with respect to the case where the heat dissipation device 10 that includes the thermally conductive material 11 and the heat dissipation plate 12 is mounted on an electronic component. However, the embodiment is not limited to such a case. For example, only the heat dissipation plate may be mounted on the electronic component without the thermally conductive material 11 interposed therebetween such that the heat absorbing surface is directly brought into contact with the electronic component. In this case, heat emitted from the electronic component is directly absorbed from the heat absorbing surface of the heat dissipation plate.

### EXAMPLES

Hereinafter, the present invention is described in more detail with reference to the Examples. However, the scope of the present invention is not limited to such Examples.

In the Examples and Comparative Examples, the following substances A1 to A6 were used as a polymerization monomer (A) having only an ethylenic unsaturated double bond-containing group as a polymerization group. In the Comparative Examples, the following substances A7 and A8 were used as a polymerization monomer (A) having an epoxy group as a polymerization group.
A1: polyfunctional urethane acrylate (Blemmer DA-800AU, manufactured by NOF CORPORATION)
A2: polyfunctional urethane acrylate (SHIKOH V-7510B, manufactured by Mitsubishi Chemical & Co., Ltd.)
A3: methacrylic group modified silicone polymer (MP-ME, manufactured by Toray Fine Chemicals Co., Ltd.)
A4: APG-100(polypropylene glycol #100 diacrylate, manufactured by SHIN-NAKAMURA CHEMICAL CO, LTD.)
A5: Nonane diol diacrylate
A6: APG-700 (polypropylene glycol #700 diacrylate, manufactured by SHIN-NAKAMURA CHEMICAL CO, LTD.)
A7: epoxy resin (EPICLON EXA4850-100, manufactured by DIC Corporation)
A8: 3,4-epoxycyclohexyl methylmethacrylate (Cyclomer M100, manufactured by Daicel Corporation)

In the Examples and the Comparative Examples, the following B1 which is thermal radical polymerization initiator, and the following B2 and B3 each of which is photo-radical polymerization initiator were used.
B1: dimethyl 2,2′-azobis (2-methyl propionate)
B2: 2-methyl-1-(4-(methylthio) phenyl)-2-morpholinopropane 1-one
B3: 2,2-dimethoxy-1,2-diphenylethane-1-one

In the Examples and the Comparative Examples, the following C1 and C2, each of which is kaolin that corresponds to the layered silicate (C), and the following C3 to C8, each of which is inorganic powder that does not correspond to the layered silicate were used.
C1: kaolin (particle size of approximately 0.1 to 4 μm, manufactured by NACALAI TESQUE, INC.)
C2: kaolin (product having a particle size that allows kaolin to pass through 350 mesh, manufactured by NACALAI TESQUE, INC.)
C3: magnesium oxide powder (HP-30, average particle size of 6 μm, manufactured by Konoshima Chemical Co., Ltd.)
C4: aluminum nitride powder (manufactured by ARBROWN Co., Ltd.)
C5: calcium chloride powder (manufactured by NACALAI TESQUE, INC.)
C6: barium sulfate powder (alumina surface-treated barium sulfate, manufactured by SAKAI CHEMICAL INDUSTRY Co., Ltd.)
C7: sodium chloride powder (manufactured by FUJIFILM Wako Pure Chemical Corporation)
C8: gallium oxide powder (manufactured by Kojundo Chemical Lab. Co., Ltd.)

### Examples 1 to 17, and Comparative Examples 2 to 8

The curable pastes of the respective Examples and the respective Comparative Examples were obtained by uniformly mixing respective materials of types and amounts described in Table 1.

With respect to the curable pastes obtained in the respective Examples 1 to 8 and the respective Comparative Examples 2 to 8, each curable paste is formed into a sheet in accordance with the following method. First, onto a PET film having a thickness of 1 mm, each of the pastes according to the respective Examples 1 to 8 and the respective Comparative Examples 2 to 8 was applied by coating using a bar coater. Next, on the thin film made of the curable paste formed on the PET film, another PET film is mounted. The thin film made of the curable paste that is sandwiched by the PET films was heated on a hot plate at a temperature of 100° C. for 15 minutes, thus obtaining a cured sheet. Thicknesses of the obtained respective sheets were described in Table 1.

With respect to the curable pastes obtained in Examples 9 to 17, each curable paste was formed into a sheet in accordance with the following method. First, onto a PET film having a thickness of 1 mm, each of the pastes according to Examples 9 to 17 was applied by coating using a bar coater. Next, on the thin film made of the curable paste formed on the PET film, another PET film is mounted. Photo curing of the thin film made of the curable paste that is sandwiched by the PET films was performed by exposing both surfaces of the thin film at an exposure amount of 1000 mJ/cm² using a parallel light UV exposure device. As a result, the cured sheet was obtained. Thicknesses of the obtained respective sheets were described in Table 1.

The radiation performances of the respective sheets were evaluated using the obtained sheets in accordance with the following method.

### Radiation Performance Evaluation

On a plate-like rubber heater with a thermocouple (manufactured by ThreeHigh Co., Ltd.), a heat conductive material layer (0.05 mm in thickness, N-777 manufactured by Shin-Etsu Chemical Co., Ltd.), a silicon layer (0.6 mm in thickness), and a heat conductive material layer (0.05 mm in thickness, N-777 manufactured by Shin-Etsu Chemical Co., Ltd.) were laminated in this order. In a state where each of the sheets obtained by the Examples and the Comparative Examples is laminated on a second heat conductive material layer, the rubber heater was heated, and the temperature at which the temperature of the rubber heater stopped rising was measured thus evaluating the radiation performance of each sheet. The rubber heater was continuously heated such that the temperature of the rubber heater was fixedly held at a temperature of 150° C. in a state where nothing was laminated on the rubber heater. The test in which nothing was laminated on the rubber heater was used as the Comparative Example 1. It should be noted that the lower the attained temperature when the temperature of the rubber heater stops rising, the higher the heat dissipating performance by radiation of the sheet becomes. The temperatures attained when the temperature of the rubber heater stopped rising are described in Table 1 with respect to the respective Examples and the respective Comparative Examples.

TABLE 1

| | | | Radical | | | | | | |
|---|---|---|---|---|---|---|---|---|---|
| | Polymerizable | | polymerization | | Layered | | | | |
| | monomer (A) | | initiator (B) | | silicate (C) | | | Thickness | Attained |
| | | Parts by | | Parts by | | Parts by | Method for | of sheet | temperature |
| | Type | mass | Type | mass | Type | mass | curing | (μm) | (° C.) |
| Ex. 1 | A1 | 50 | B1 | 2.5 | C1 | 50 | Thermal | 1155 | 111.3 |
| Ex. 2 | A1 | 70 | B1 | 2.5 | C1 | 50 | Thermal | 529 | 108.7 |
| Ex. 3 | A1 | 50 | B1 | 2.5 | C1 | 50 | Thermal | 921 | 108.3 |
| Ex. 4 | A1 | 50 | B1 | 2.5 | C1 | 50 | Thermal | 2432 | 106.6 |
| Ex. 5 | A1 | 70 | B1 | 2.5 | C2 | 30 | Thermal | 580 | 117.1 |
| Ex. 6 | A1 | 60 | B1 | 2.5 | C2 | 40 | Thermal | 730 | 115.9 |
| Ex. 7 | A1 | 50 | B1 | 2.5 | C2 | 50 | Thermal | 1160 | 108.5 |
| Ex. 8 | A1 | 25 | B1 | 2.5 | C2 | 50 | Thermal | 1230 | 111.7 |
| | A3 | 25 | | | | | | | |
| Ex. 9 | A2 | 50 | B1 | 2.5 | C2 | 50 | Photo | 1090 | 111.8 |
| Ex. 10 | A1 | 50 | B2 | 3.0 | C2 | 50 | Photo | 1130 | 108.3 |
| | A4 | 5 | | | | | | | |
| Ex. 11 | A1 | 50 | B2 | 2.5 | C2 | 50 | Photo | 1240 | 111.0 |
| Ex. 12 | A2 | 50 | B2 | 2.5 | C2 | 50 | Photo | 1320 | 109.0 |
| Ex. 13 | A2 | 50 | B2 | 3.0 | C2 | 50 | Photo | 1050 | 110.0 |
| | A4 | 5 | | | | | | | |
| Ex. 14 | A4 | 50 | B2 | 3.0 | C2 | 50 | Photo | 560 | 108.3 |
| Ex. 15 | A2 | 50 | B3 | 2.0 | C2 | 50 | Photo | 1320 | 111.6 |
| Ex. 16 | A5 | 50 | B3 | 2.0 | C2 | 50 | Photo | 1020 | 108.8 |
| Ex. 17 | A6 | 50 | B3 | 2.0 | C2 | 50 | Photo | 510 | 107.8 |
| Comp. Ex. 1 | — | — | — | — | — | — | — | — | 150 |
| Comp. Ex. 2 | A7 | 35 | B1 | 1.0 | C1 | 50 | Photo | 1125 | 121.5 |
| | A8 | 15 | | | | | | | |
| Comp. Ex. 3 | A1 | 50 | B1 | 2.5 | C3 | 50 | Photo | 512 | 121.1 |
| Comp. Ex. 4 | A1 | 50 | B1 | 2.5 | C4 | 50 | Photo | 530 | 122.5 |
| Comp. Ex. 5 | A1 | 50 | B1 | 2.5 | C5 | 50 | Photo | 650 | 121.4 |
| Comp. Ex. 6 | A1 | 50 | B1 | 2.5 | C6 | 50 | Photo | 1010 | 121.9 |
| Comp. Ex. 7 | A1 | 50 | B1 | 2.5 | C7 | 50 | Photo | 1450 | 121.4 |
| Comp. Ex. 8 | A1 | 50 | B1 | 2.5 | C8 | 50 | Photo | 710 | 121.5 |

According to Table 1, with respect to all radiation sheets of Examples 1 to 17, each of which is formed of the cured material made of the curable paste that contains a polymerizable monomer (A) that has only an ethylenic unsaturated double bond-containing group as a polymerizable group, a radical polymerization initiator (B) and a layered silicate (C), all attained temperatures of 120° C. or below. Accordingly, it is understood that all radiation sheets of Examples 1 to 17 are excellent in heat dissipating performance derived from radiation. On the other hand, with respect to all radiation sheets of Comparative Examples 2 to 8, each of which is formed of the cured material made of the curable paste that contains a polymerizable monomer (A) having an epoxy group as a polymerizable group or contains inorganic powder other than the layered silicate (C), all attained temperatures of 120° C. or higher. Accordingly, it is understood that all radiation sheets of Comparative Examples 2 to 8 are poor in heat dissipating performance derived from radiation.

### Examples 18 to 20, Comparative Example 9 and Comparative Example 10

With respect to Examples 18 to 20, the curable pastes of the respective Examples and the respective Comparative Examples were obtained by uniformly mixing respective materials of types and amounts described in Table 2. With respect to the curable pastes obtained in the respective Examples 18 to 20, each curable paste is formed into a sheet in accordance with the following method. First, onto a PET film having a thickness of 1 mm, each of the pastes according to Examples 18 to 20 was applied by coating using a bar coater. Next, on the thin film made of the curable paste formed on the PET film, another PET film is mounted. The thin film made of the curable paste that is sandwiched by the PET films was heated on the hot plate at a temperature of 100° C. for 15 minutes. As a result, the cured sheet was obtained. Thicknesses of the obtained respective sheets were described in Table 2.

### Radiation Performance Evaluation

On a sheet heating element FL heater (manufactured by Shinwa Rules Co., Ltd.), a heat conductive material layer (0.05 mm in thickness, N-777 manufactured by Shin-Etsu Chemical Co., Ltd.), a copper foil (0.025 mm in thickness), and a heat conductive material layer (0.05 mm in thickness, N-777 manufactured by Shin-Etsu Chemical Co., Ltd.) were laminated in this order. In a state where each of the sheets obtained by Examples 18 to 20 is laminated on a heat conductive material layer that is not brought into contact with the FL heater, the FL heater was heated, and a temperature at which the temperature of the FL heater stopped rising was measured, thus evaluating the radiation performance of each sheet. The FL heater was continuously heated such that the temperature of the FL heater was fixedly held at a temperature of 100° C. in a state where nothing was laminated on the FL heater. The test performed in a state where nothing was laminated on the FL heater was used as Comparative Example 9. The test performed in a state where a heat conductive material layer and a copper foil are laminated on the FL heater was used as Comparative Example 10. It should be noted that the lower the attained temperature when the temperature of the FL heater stopped rising, the higher the heat dissipating performance by radiation of the sheet becomes. The attained temperatures when the temperature of the FL heater stopped rising are described in Table 2 with respect to the respective Examples and the respective Comparative Examples.

TABLE 2

| | | | Radical | | | | | | |
|---|---|---|---|---|---|---|---|---|---|
| | Polymerizable | | polymerization | | Layered | | | | |
| | monomer (A) | | initiator (B) | | silicate (C) | | | Thickness | Attained |
| | | Parts by | | Parts by | | Parts by | Method for | of sheet | temperature |
| | Type | mass | Type | mass | Type | mass | curing | (μm) | (° C.) |
| Ex. 18 | A1 | 50 | B1 | 2.5 | C1 | 40 | Thermal | 630 | 67.3 |
| Ex. 19 | A1 | 50 | B1 | 2.5 | C1 | 50 | Thermal | 630 | 66.8 |
| Ex. 20 | A1 | 50 | B1 | 2.5 | C1 | 60 | Thermal | 630 | 64.8 |
| Comp. Ex. 9 | — | — | — | — | — | — | — | — | 100.9 |
| Comp. Ex. 10 | — | — | — | — | — | — | — | Copper foil | 83.6 |

According to Table 2, with respect to all radiation sheets of Examples 18 to 20, each of which is formed of the cured material made of the curable paste that contains a polymerizable monomer (A) that has only an ethylenic unsaturated double bond-containing group as a polymerizable group, a radical polymerization initiator (B) and a layered silicate (C), all attained temperatures of 70° C. or below. Accordingly, it is understood that all radiation sheets of Examples 18 to 20 are excellent in heat dissipating performance derived from radiation. On the other hand, in the case of the Comparative Example 10 in which only a copper foil is laminated, the attained temperature was 80° C. or higher. Accordingly, it is understood that the radiation sheet of Comparative Example 10 was poor in heat dissipating performance derived from radiation.

### EXPLANATION OF REFERENCE NUMERALS

4 electronic component
10 heat dissipation device
12 heat dissipation plate
12a heat absorbing surface
12b heat dissipating surface

What is claimed is:

1. A radiation sheet comprising a cured material of a curable paste comprising a polymerizable monomer (A), a radical polymerization initiator (B) and a layered silicate (C),
the polymerizable monomer (A) having only an ethylenic unsaturated double bond-containing group as a polymerizable group.

2. The radiation sheet according to claim 1, wherein the layered silicate (C) comprises kaolin.

3. The radiation sheet according to claim 1, wherein the polymerizable monomer (A) comprises a polyfunctional polymerizable monomer having two or more ethylenic unsaturated double bonds.

4. The radiation sheet according to claim 1, wherein the polyfunctional polymerizable monomer comprises one or more types of compounds selected from urethane (meth)acrylate compounds and di(meth)acrylates of glycols.

5. The radiation sheet according to claim 1, wherein a ratio of a mass of the layered silicate (C) with respect to a mass of the radiation sheet is 20% by mass or more and 80% by mass or less.

6. The radiation sheet according to claim 5, wherein the ratio of a mass of the layered silicate (C) with respect to a mass of the radiation sheet is 25% by mass or more and 60% by mass or less.

7. The radiation sheet according to claim 1, wherein a thickness of the radiation sheet is 400 μm or more and 2500 μm or less.

8. A heat dissipation plate comprising the radiation sheet according to claim 1, wherein the heat dissipation plate has: a heat absorbing surface that is formed on one surface of the heat dissipation plate and absorbs heat emitted from a heat generation source; and a heat dissipating surface that is formed on the other surface of the heat dissipation plate and dissipates at least a portion of the heat absorbed from the heat absorbing surface.

9. A heat dissipation device comprising the heat dissipation plate according to claim 8.

10. A curable paste used for forming the radiation sheet according to claim 1, wherein
the curable paste comprises a polymerizable monomer (A), a radical polymerization initiator (B) and a layered silicate (C), and
the polymerizable monomer (A) has only an ethylenic unsaturated double bond-containing group as a polymerizable group.
